(19) United States
(12) Patent Application Publication
(10) Pub. No.: US 2021/0209993 A1
(43) Pub. Date: Jul. 8, 2021

(54) SHIFT REGISTER, GATE DRIVER-ON-ARRAY CIRCUIT AND DRIVING METHOD THEREOF, DISPLAY DEVICE

(71) Applicants: BOE TECHNOLOGY GROUP CO., LTD., Beijing (CN); HEFEI XINSHENG OPTOELECTRONICS TECHNOLOGY CO., LTD., Hefei, Anhui (CN)

(72) Inventors: Jing SUN, Beijing (CN); Jinliang LIU, Beijing (CN); Jian ZHAO, Beijing (CN); Miao ZHANG, Beijing (CN)

(21) Appl. No.: 16/064,834

(22) PCT Filed: Dec. 5, 2017
(86) PCT No.: PCT/CN2017/114582

§ 371 Date: Jun. 21, 2018

(30) Foreign Application Priority Data
Mar. 8, 2017 (CN) 201710136096.8

(51) Int. Cl. G09G 3/20

(52) U.S. Cl. CPC G09G 3/2092; G09G 2310/0286; G09G 2310/08; G09G 2310/061; G09G 2320/045; G09G 2300/0426

(57) ABSTRACT

The present application provides shift register, gate driver-on-array circuit and driving method thereof, display device. The shift register includes input sub-circuit, output sub-circuit and step-down sub-circuit. The input sub-circuit is configured to, in input stage, charge pull-up node to first voltage level based on signal input from signal input terminal. The output sub-circuit is configured to, in output stage, pull up voltage level at pull-up node to second voltage level. The step-down sub-circuit is configured to, in output stage, pull down voltage level at pull-up node from second voltage level to third voltage level after voltage level at pull-up node is pulled up to second voltage level. The output sub-circuit is further configured to, in output stage, output first clock signal input from first clock signal input terminal through signal output terminal under control of pull-up node.

### CROSS-REFERENCE TO RELATED APPLICATIONS

This is a National Phase Application filed under 35 U.S.C. 371 as a national stage of PCT/CN2017/114582, filed on Dec. 5, 2017, an application claiming the benefit of Chinese Patent Application No. 201710136096.8, filed on Mar. 8, 2017, the contents of which are incorporated by reference in the entirety.

### TECHNICAL FIELD

The present disclosure relates to the field of display technology, more particularly, to a shift register, a gate driver-on-array circuit and a driving method thereof, and a display device.

### BACKGROUND

Generally, a liquid crystal display panel includes a matrix of pixels in vertical and horizontal arrays. In a display process, a gate driving circuit is configured to generate gate scanning signals for pixels, and the gate driving circuit outputs the gate scanning signals to scan respective pixels line by line.

In the related art, the driving circuit in the liquid crystal panel is implemented by providing an integrated circuit (IC) in a peripheral area of the liquid crystal panel. In contrast, GOA (Gate driver-On-Array) is a technique in which a gate driving circuit is integrated onto an array substrate. Each GOA unit has a shift register, which includes a plurality of thin film transistors and a capacitor and transfers a scanning signal to a next GOA unit, thereby turning on the thin film transistors line by line and achieving input of data signals to pixel units.

### SUMMARY

The present disclosure provides a shift register, a gate driver-on-array circuit and a driving method thereof, and a display device.

In an aspect, the present disclosure provides a shift register including an input sub-circuit, an output sub-circuit and a step-down sub-circuit; the input sub-circuit is coupled to a signal input terminal and a pull-up node; the output sub-circuit is coupled to a first clock signal input terminal, a signal output terminal, the step-down sub-circuit and the pull-up node; the step-down sub-circuit is further coupled to the pull-up node and the signal output terminal; the pull-up node is a node connected in between the input sub-circuit, the output sub-circuit and the step-down sub-circuit; the input sub-circuit is configured to, in an input stage, charge the pull-up node to a first voltage level based on a signal input from the signal input terminal; the output sub-circuit is configured to, in an output stage, pull up a voltage level at the pull-up node to a second voltage level; the step-down sub-circuit is configured to, in the output stage, pull down the voltage level at the pull-up node from the second voltage level to a third voltage level after the voltage level at the pull-up node is pulled up to the second voltage level, the third voltage level being greater than the first voltage level; and the output sub-circuit is further configured to, in the output stage, output a first clock signal, which is input from the first clock signal input terminal, through the signal output terminal under control of the pull-up node.

Optionally, the step-down sub-circuit includes a switching transistor having a first electrode coupled to the output sub-circuit and the pull-up node, a second electrode coupled to a control electrode of the switching transistor, the output sub-circuit and the signal output terminal, and the control electrode coupled to the output sub-circuit and the signal output terminal.

Optionally, the input sub-circuit includes a first transistor having a first electrode coupled to the signal input terminal and a second electrode coupled to the pull-up node.

Optionally, the output sub-circuit includes a third transistor and a storage capacitor; a first electrode of the third transistor is coupled to the first clock signal input terminal, a second electrode of the third transistor is coupled to a second terminal of the storage capacitor and the step-down sub-circuit, and a control electrode of the third transistor is coupled to the pull-up node and a first terminal of the storage capacitor.

Optionally, the shift register further includes an output reset sub-circuit, a pull-up node reset sub-circuit, a pull-down sub-circuit, a pull-down control sub-circuit, a noise reduction sub-circuit and a step-up sub-circuit; the output reset sub-circuit is coupled to a reset signal input terminal, a first signal input terminal and the signal output terminal, and is configured to reset the signal output from the signal output terminal; the pull-up node reset sub-circuit is coupled to the reset signal input terminal, the first signal input terminal and the pull-up node, and is configured to reset the voltage level at the pull-up node; the pull-down control sub-circuit is coupled to a pull-down node and a second clock signal input terminal, and is configured to control a voltage level at the pull-down node based on a second clock signal input from the second clock signal input terminal, the pull-down node being a node connected in between the pull-down control sub-circuit and the pull-down sub-circuit; the pull-down sub-circuit is coupled to the pull-down node, the pull-up node, the pull-down control sub-circuit and the first signal input terminal, and is configured to pull down, under control of the voltage level at the pull-up node, the voltage level at the pull-down node through a first signal input from the first signal input terminal; the noise reduction sub-circuit is coupled to the input sub-circuit, the first signal input terminal, the pull-down node, the pull-up node, the output sub-circuit, the signal output terminal and the second clock signal input terminal, and is configured to reduce output noise at the pull-up node and output noise at the signal output terminal through the first signal input from the first signal input terminal; and the step-up sub-circuit is coupled to the signal input terminal, the input sub-circuit, the second clock signal input terminal and the pull-up node, and is configured to step up the signal input from the signal input terminal based on the second clock signal input from the second clock signal input terminal.

Optionally, the output reset sub-circuit includes a fourth transistor having a first electrode coupled to the step-down sub-circuit, the output sub-circuit and the signal output terminal, a second electrode coupled to the first signal input terminal, and a control electrode coupled to the reset signal input terminal.

Optionally, the pull-up node reset sub-circuit includes a second transistor having a first electrode coupled to the pull-up node, a second electrode coupled to the first signal input terminal, and a control electrode coupled to the reset signal input terminal.

Optionally, the pull-down sub-circuit includes a sixth transistor and an eighth transistor; a first electrode of the sixth transistor is coupled to the pull-down node, a second electrode of the sixth transistor is coupled to the first signal input terminal, and a control electrode of the sixth transistor is coupled to the pull-up node; and a first electrode of the eighth transistor is coupled to the pull-down control sub-circuit, a second electrode of the eighth transistor is coupled to the first signal input terminal, and a control electrode of the eighth transistor is coupled to the pull-up node.

Optionally, the pull-down control sub-circuit includes a fifth transistor, a ninth transistor and a pull-down control node; a first electrode of the fifth transistor is coupled to a first electrode of the ninth transistor and the second clock signal input terminal, a second electrode of the fifth transistor is coupled to the pull-down node, and a control electrode of the fifth transistor is coupled to the pull-down control node; and a second electrode of the ninth transistor is coupled to the pull-down control node, and a control electrode of the ninth transistor is coupled to the second clock signal input terminal.

Optionally, the noise reduction sub-circuit includes a tenth transistor, an eleventh transistor and a twelfth transistor; a first electrode of the tenth transistor is coupled to the input sub-circuit and the pull-up node, a second electrode of the tenth transistor is coupled to the first signal input terminal, and a control electrode of the tenth transistor is coupled to the pull-down node; a first electrode of the eleventh transistor is coupled to the output sub-circuit and the signal output terminal, a second electrode of the eleventh transistor is coupled to the first signal input terminal, and a control electrode of the eleventh transistor is coupled to the pull-down node; and a first electrode of the twelfth transistor is coupled to the signal output terminal, a second electrode of the twelfth transistor is coupled to the first signal input terminal, and a control electrode of the twelfth transistor is coupled to the second clock signal input terminal.

Optionally, the step-up sub-circuit includes a thirteenth transistor having a first electrode coupled to the signal input terminal, a second electrode coupled to the pull-up node, and a control electrode coupled to the second clock signal input terminal.

In another aspect, the present disclosure further provides a gate driver-on-array circuit including a plurality of stages of shift registers described herein, a signal output from a gate driving signal generation unit of each stage of shift register serves as an input signal of an signal input terminal of a next stage of shift register; and a signal output from an signal output terminal of each stage of shift register is configured to drive a gate line and serves as a reset signal of a reset signal terminal of a previous stage of shift register.

In another aspect, the present disclosure further provides a display device including the above gate driver-on-array circuit.

In another aspect, the present disclosure further provides a method for driving a gate driver-on-array circuit, the gate driver-on-array circuit including a plurality of stages of the shift registers described herein, and the method includes:

in an input stage, charging, by the input sub-circuit, the pull-up node to the first voltage level based on the signal input from the signal input terminal;

in an output stage, pulling up the voltage level at the pull-up node to the second voltage level and outputting the first clock signal, which is input from the first clock signal input terminal, through the signal output terminal under control of the pull-up node, by the output sub-circuit; and pulling down, by the step-down sub-circuit, the voltage level at the pull-up node from the second voltage level to the third voltage level, the third voltage level being greater than the first voltage level.

Optionally, in a case of using the above shift register, the method for driving the gate driver-on-array circuit further includes: in a reset and noise reduction stage, resetting the signal output from the signal output terminal and the voltage level at the pull-up node.

### BRIEF DESCRIPTION OF THE DRAWINGS

FIG. 1 is a schematic diagram illustrating a structure of a shift register according to an embodiment of the present disclosure;

FIG. 2 is a schematic diagram illustrating a circuit of a shift register according to an embodiment of the present disclosure;

FIG. 3 is a timing diagram illustrating an operation of a shift register according to an embodiment of the present disclosure;

FIG. 4 is a schematic diagram illustrating a structure of a shift register according to an embodiment of the present disclosure;

FIG. 5 is a schematic diagram illustrating a circuit of a shift register according to an embodiment of the present disclosure;

FIG. 6 is a timing diagram illustrating an operation of a shift register according to an embodiment of the present disclosure;

FIG. 7 is a schematic diagram illustrating a structure of a gate driver-on-array circuit according to an embodiment of the present disclosure; and

FIG. 8 is a flow chart illustrating a method for driving a gate driver-on-array circuit according to an embodiment of the present disclosure.

### DETAILED DESCRIPTION

To make those skilled in the art better understand the technical solutions of the present disclosure, the present disclosure will be described in detail below in conjunction with the accompanying drawings and specific embodiments.

Generally, a liquid crystal display panel includes a matrix of pixels in vertical and horizontal arrays. In a display process, a gate driving circuit is configured to generate gate scanning signals for pixels, and the gate driving circuit outputs the gate scanning signals to scan respective pixels line by line.

In the related art, the driving circuit in the liquid crystal panel is implemented by providing an integrated circuit (IC) in a peripheral area of the liquid crystal panel. In contrast, GOA (Gate driver-On-Array) is a technique in which a gate driving circuit is integrated onto an array substrate. Each GOA unit has a shift register, which includes a plurality of thin film transistors and a capacitor and transfers a scanning signal to a next GOA unit, thereby turning on the thin film transistors line by line and achieving input of data signals to pixel units.

By having the GOA driving circuit, in which the GOA units are directly fabricated onto the array substrate, the need of gate driver IC can be eliminated and production cost can be lowered. Meanwhile, the gate IC bonding process is eliminated, thereby improving yield of product and facilitating implementation of narrow bezel. Therefore, GOA driving circuits have been widely used.

Existing GOA units achieve shifting output of each row on the array panel through clock signals (CLK), where an output signal of a row serves as an input signal of a next row, and an output signal of the next row serves as a reset signal of the row. However, when the signal is output from each row, a voltage level at a pull-up node (PU) is instantly increased to about twice as much as an output voltage due to the bootstrap effect of a capacitor in the GOA driving circuit, such that a drift occurs in the characteristic curves of the TFT devices whose gates are coupled to the PU node, thereby affecting normal operations of part of the TFT devices, which in turn results in display defects such as image display abnormal defect (AD) generated in the liquid crystal panel.

Accordingly, the present disclosure provides, inter alia, a shift register, a gate driver-on-array circuit, a driving method thereof and a display device that substantially obviate one or more of the problems due to limitations and disadvantages of the related art.

The transistors employed in the embodiments of the present disclosure may be thin film transistors or filed effect transistors or other devices having similar characteristics. Due to the symmetry of the source and drain of the employed transistor, there is no distinction between the source and the drain. In the embodiments of the present disclosure, in order to distinguish the source and the drain of the transistor, one of them is referred to as a first electrode, and the other one is referred to as a second electrode, and a gate of the transistor is referred to as a control electrode. Further, transistors may be classified into N type transistors and P type transistors based on their characteristics, and the following description of the embodiments is made by taking N type transistors as an example. For an N type transistor, the first electrode is a source of the N type transistor, the second electrode is a drain of the N type transistor, and the source and the drain are conducted when a high level is input to a gate of the N type transistor. It is the opposite for a P type transistor. Use of P type transistors can be easily conceived by those skilled in the art without any creative work, and therefore belongs to the protection scope of the embodiments of the present disclosure.

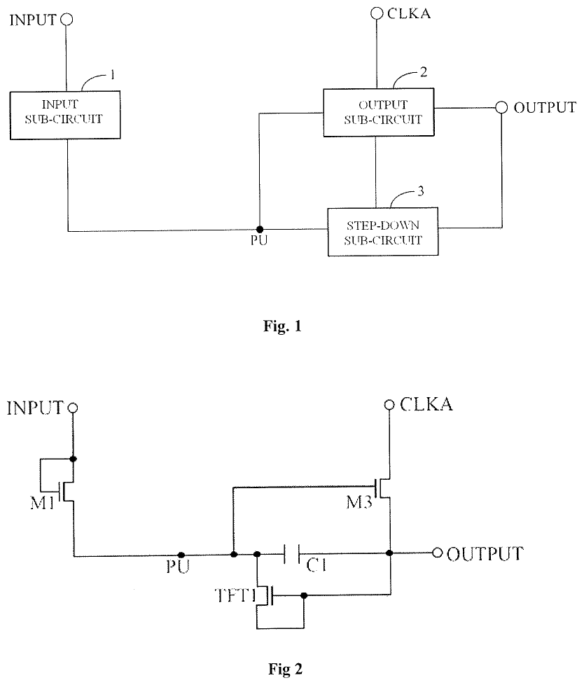

An embodiment of the present disclosure provides a shift register. Referring to FIGS. 1 to 3, the shift register includes an input sub-circuit 1, an output sub-circuit 2 and a step-down sub-circuit 3.

FIG. 1 is a schematic diagram illustrating a structure of a shift register according to an embodiment of the present disclosure. As illustrated in FIG. 1, the input sub-circuit 1 is coupled to a signal input terminal INPUT and a pull-up node PU. The output sub-circuit 2 is coupled to a first clock signal input terminal CLKA, a signal output terminal OUTPUT, the step-down sub-circuit 3 and the pull-up node PU. The step-down sub-circuit 3 is further coupled to the pull-up node PU and the signal output terminal OUTPUT. The pull-up node PU is a node connected in between the input sub-circuit 1, the output sub-circuit 2 and the step-down sub-circuit 3.

The input sub-circuit 1 is configured to, in an input stage, charge the pull-up node PU to a first voltage level based on a signal input from the signal input terminal INPUT.

The output sub-circuit 2 is configured to, in an output stage, pull up a voltage level at the pull-up node PU to a second voltage level.

The step-down sub-circuit 3 is configured to, in the output stage, pull down the voltage level at the pull-up node PU from the second voltage level to a third voltage level after the voltage level at the pull-up node PU is pulled up to the second voltage level, the third voltage level being greater than the first voltage level.

The output sub-circuit 2 is further configured to, in the output stage, output a first clock signal input from the first clock signal input terminal CLKA through the signal output terminal OUTPUT under control of the pull-up node PU.

From FIG. 1 it can be seen that, the input sub-circuit 1, the output sub-circuit 2 and the step-down sub-circuit 3 are each coupled to the pull-up node PU. In the input stage, the input sub-circuit 1 transfers the signal input from the signal input terminal to the pull-up node PU, such that the voltage level at the pull-up node PU is increased to the first voltage level. At the moment of starting the output stage, the input sub-circuit 2 pulls up the voltage level at the pull-up node PU from the first voltage level to the second voltage level; subsequently (also in the output stage), the step-down sub-circuit 3 pulls down the voltage level at the PU from the second voltage level to the third voltage level, the third voltage level being greater than the first voltage level. In this case, as the step-down sub-circuit 3 has pulled down the voltage level at the pull-up node PU, it is possible to avoid occurrence of drift in the characteristic curve of the TFT device whose gate is coupled to the pull-up node, which in turn allows the TFT device to operate as normal, thereby avoiding display defects such as AD generated in the liquid crystal panel.

It should be noted that the third voltage level is generally greater than the first voltage level, however, in a case where the signal output terminal OUTPUT continues its output for a sufficient long time, the third voltage level may be equal to the first voltage level, the description of this case will not be discussed herein.

FIG. 2 is a schematic diagram illustrating a circuit of a shift register according to an embodiment of the present disclosure. As illustrated in FIG. 2, in the present embodiment, the step-down sub-circuit 3 includes a switching transistor TFT1 having a first electrode coupled to the output sub-circuit 2 and the pull-up node PU, a second electrode coupled to a control electrode of the switching transistor TFT1, the output sub-circuit 2 and the signal output terminal OUTPUT, and the control electrode coupled to the output sub-circuit 2 and the signal output terminal OUTPUT.

As illustrated in FIG. 2, in the present embodiment, the input sub-circuit 1 includes a first transistor M1 having a first electrode coupled to the signal input terminal INPUT and a second electrode coupled to the pull-up node PU.

As illustrated in FIG. 2, in the present embodiment, the output sub-circuit 2 includes a third transistor M3 and a storage capacitor C1. A first electrode of the third transistor M3 is coupled to the first clock signal input terminal CLKA, a second electrode of the third transistor M3 is coupled to a second terminal of the storage capacitor C1 and the step-down sub-circuit 3, and a control electrode of the third transistor M3 is coupled to the pull-up node PU and a first terminal of the storage capacitor C1.

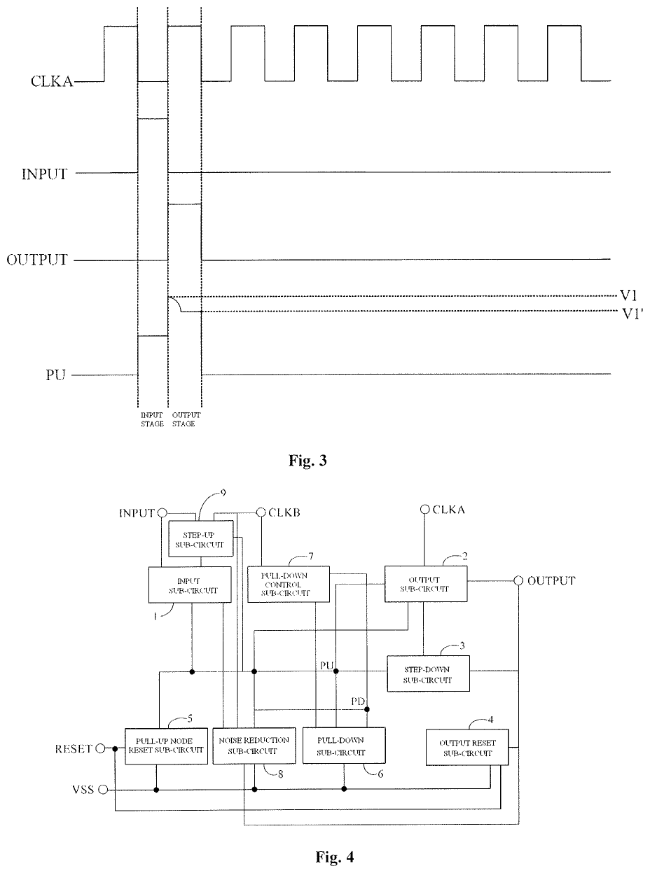

Next, the operation principle of the shift register in the present embodiment will be described with reference to FIG. 3. FIG. 3 is a timing diagram illustrating an operation of a shift register according to an embodiment of the present disclosure.

As illustrated in FIG. 3, in an input stage, a high level is input from the signal input terminal INPUT, the first transistor M1 is turned on, such that a voltage level at the pull-up node PU is increased to a first voltage level, and meanwhile, the storage capacitor C1 is charged; in addition, the third transistor M3 is turned on, and at this time, the first clock signal (at a low level) input from the first clock signal input terminal CLKA is output from the signal output terminal OUTPUT.

As illustrated in FIG. 3, in an output stage, a low level is input from the signal input terminal INPUT, and the first transistor M1 is turned off. However, the voltage level at the pull-up node PU continues to increase to a second voltage level (V1) due to the existence of the storage capacitor C1, and the third transistor M3 remains on. At this time, the first clock signal (at a high level) is input from the first clock signal input terminal CLKA, and the first clock signal (at the high level) is output from the signal output terminal OUTPUT (i.e., as a signal input from the signal input terminal INPUT at the next row). Due to the bootstrap effect of the storage capacitor C1, the voltage at the pull-up node PU is increased to approximately twice as much as the voltage output from the signal output terminal OUTPUT and turns on the switching transistor TFT1, such that the pull-up node PU and the signal output terminal OUTPUT forms a loop via the switching transistor TFT1, which results in that the voltage level at the pull-up node PU is instantly decreased to a third voltage level (V1′), i.e., V1′<V1.

That is, during a time period after starting of the output stage, the voltage level at the pull-up node PU at the moment of starting the output stage is pulled down, due to the turning-on of the switching transistor TFT1. Therefore, occurrence of drift in the characteristic curve of the TFT device whose gate is coupled to the pull-up node PU is avoided, which in turn allows the TFT device to operate as normal, thereby avoiding display defects such as AD generated in the liquid crystal panel.

The shift register in the present embodiment includes the input sub-circuit 1, the output sub-circuit 2 and the step-down sub-circuit 3. In the output stage, the step-down sub-circuit 3 is capable of pulling down the voltage level at the pull-up node PU from the second voltage level to the third voltage level after the voltage level at the pull-up node PU is pulled up to the second voltage level, such that the voltage at the pull-up node PU is instantly decreased, thereby avoiding occurrence of drift in the characteristic curve of the TFT device whose gate is coupled to the pull-up node PU, which in turn allows the TFT device to operate as normal, thereby avoiding display defects such as AD generated in the liquid crystal panel.

An embodiment of the present disclosure further provides a shift register. Referring to FIGS. 4 to 6, the shift register in the present embodiment has a similar structure as that of the shift register in the embodiment shown in FIG. 1, except that the shift register in the present embodiment further includes an output reset sub-circuit 4, a pull-up node reset sub-circuit 5, a pull-down sub-circuit 6, a pull-down control sub-circuit 7, a noise reduction sub-circuit 8 and a step-up sub-circuit 9.

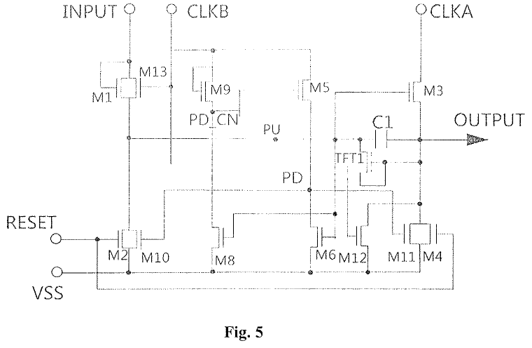

FIG. 4 is a schematic diagram illustrating a structure of a shift register according to an embodiment of the present disclosure; FIG. 5 is a schematic diagram illustrating a circuit of a shift register according to an embodiment of the present disclosure; and FIG. 6 is a timing diagram illustrating an operation of a shift register according to an embodiment of the present disclosure.

As illustrated in FIG. 4, the output reset sub-circuit 4 is coupled to a reset signal input terminal RESET, a first signal input terminal VSS and the signal output terminal OUTPUT, and is configured to reset the signal output from the signal output terminal OUTPUT.

As illustrated in FIG. 5, the output reset sub-circuit 4 in the present embodiment includes a fourth transistor M4 having a first electrode coupled to the step-down sub-circuit 3, the output sub-circuit 2 and the signal output terminal OUTPUT, a second electrode coupled to the first signal input terminal VSS, and a control electrode coupled to the reset signal input terminal RESET.

As illustrated in FIG. 4, the pull-up node reset sub-circuit 5 is coupled to the reset signal input terminal RESET, the first signal input terminal VSS and the pull-up node PU, and is configured to reset the voltage level at the pull-up node PU.

As illustrated in FIG. 5, the pull-up node reset sub-circuit 5 in the present embodiment includes a second transistor M2 having a first electrode coupled to the pull-up node PU, a second electrode coupled to the first signal input terminal VSS, and a control electrode coupled to the reset signal input terminal RESET.

As illustrated in FIG. 4, the pull-down control sub-circuit 7 is coupled to a pull-down node PD and a second clock signal input terminal CLKB, and is configured to control a voltage level at the pull-down node PD based on a second clock signal input from the second clock signal input terminal CLKB, the pull-down node PD being a node connected in between the pull-down control sub-circuit 7 and the pull-down sub-circuit 6.

As illustrated in FIG. 5, the pull-down control sub-circuit 7 in the present embodiment includes a fifth transistor M5, a ninth transistor M9 and a pull-down control node PD_CN.

A first electrode of the fifth transistor M5 is coupled to a first electrode of the ninth transistor M9 and the second clock signal input terminal CLKB, a second electrode of the fifth transistor M5 is coupled to the pull-down node PD, and a control electrode of the fifth transistor M5 is coupled to the pull-down control node PD-CN.

A second electrode of the ninth transistor M9 is coupled to the pull-down control node PD_CN, and a control electrode of the ninth transistor M9 is coupled to the second clock signal input terminal CLKB.

As illustrated in FIG. 4, the pull-down sub-circuit 6 is coupled to the pull-down node PD, the pull-up node PU, the pull-down control sub-circuit 7 and the first signal input terminal VSS, and is configured to pull down, under control of the voltage level at the pull-up node PU, the voltage level at the pull-down node PD through a first signal input from the first signal input terminal VSS.

As illustrated in FIG. 5, the pull-down sub-circuit 6 in the present embodiment includes a sixth transistor M6 and an eighth transistor M8.

A first electrode of the sixth transistor M6 is coupled to the pull-down node PD, a second electrode of the sixth transistor M6 is coupled to the first signal input terminal VSS, and a control electrode of the sixth transistor M6 is coupled to the pull-up node PU.

A first electrode of the eighth transistor M8 is coupled to the pull-down control sub-circuit 7, a second electrode of the eighth transistor M8 is coupled to the first signal input terminal VSS, and a control electrode of the eighth transistor M8 is coupled to the pull-up node PU.

As illustrated in FIG. 4, the noise reduction sub-circuit 8 is coupled to the input sub-circuit 1, the first signal input terminal VSS, the pull-down node PD, the pull-up node PU, the output sub-circuit 2, the signal output terminal OUTPUT and the second clock signal input terminal CLKB, and is configured to reduce output noise at the pull-up node PU and output noise at the signal output terminal OUTPUT through the first signal input from the first signal input terminal VSS.

As illustrated in FIG. 5, the noise reduction sub-circuit 8 in the present embodiment includes a tenth transistor M10, an eleventh transistor M11 and a twelfth transistor M12.

A first electrode of the tenth transistor M10 is coupled to the input sub-circuit 1 and the pull-up node PU, a second electrode of the tenth transistor M10 is coupled to the first signal input terminal VSS, and a control electrode of the tenth transistor M10 is coupled to the pull-down node PD.

A first electrode of the eleventh transistor M11 is coupled to the output sub-circuit 2 and the signal output terminal OUTPUT, a second electrode of the eleventh transistor M11 is coupled to the first signal input terminal VSS, and a control electrode of the eleventh transistor M11 is coupled to the pull-down node PD.

A first electrode of the twelfth transistor M12 is coupled to the signal output terminal OUTPUT, a second electrode of the twelfth transistor M12 is coupled to the first signal input terminal VSS, and a control electrode of the twelfth transistor M12 is coupled to the second clock signal input terminal CLKB.

As illustrated in FIG. 4, the step-up sub-circuit 9 is coupled to the signal input terminal INPUT, the input sub-circuit 1, the second clock signal input terminal CLKB and the pull-up node PU, and is configured to step up the signal input from the signal input terminal INPUT based on the second clock signal input from the second clock signal input terminal CLKB.

As illustrated in FIG. 5, the step-up sub-circuit 9 in the present embodiment includes a thirteenth transistor M13 having a first electrode coupled to the signal input terminal INPUT, a second electrode coupled to the pull-up node PU, and a control electrode coupled to the second clock signal input terminal CLKB.

The operation principles of the input sub-circuit 1, the output sub-circuit 2 and the step-down sub-circuit 3 of the shift register in the present embodiment are the same as those in the embodiment shown in FIG. 1, and thus will not be repeatedly described here.

Next, the operation principle of the shift register (including the output reset sub-circuit 4, the pull-up node reset sub-circuit 5, the pull-down sub-circuit 6, the pull-down control sub-circuit 7, the noise reduction sub-circuit 8 and the step-up sub-circuit 9) in the present embodiment will be described with reference to the timing diagram as shown in FIG. 6. In the present embodiment, the first signal input terminal VSS always outputs a low level in the shift register.

As illustrated in FIG. 6, in an input stage, the second clock signal input terminal CLKB inputs a high level, and the thirteenth transistor M13 is turned on to step up a voltage level at the pull-up node PU.

As illustrated in FIG. 6, in an output stage, the pull-up node PU is at a high level, and the sixth transistor M6 and the eighth transistor M8 are turned on, so that the pull-down node PD and the pull-down control node PD_CN are coupled with the first signal input terminal VSS, respectively, and a voltage level at the pull-down node PD is pulled down to a low level (the pull-down control node PD_CN is also pulled down to a low level to avoid affecting the voltage level at the pull-down node PD). As a result, the tenth transistor M10 and the eleventh transistor M11 are turned off, such that a case in which the voltage level at the pull-up node PU is unstable due to turning-on of the tenth transistor M10 and the signal output from the signal output terminal OUTPUT is unstable due to turning-on of the eleventh transistor M11 is avoided.

As illustrated in FIG. 6, a reset and noise reduction stage following the output stage is included.

In the reset and noise reduction stage:

(1) the reset signal input terminal RESET inputs a high level, and the second transistor M2 is turned on, so that the pull-up node PU is coupled with the first signal input terminal VSS via the second transistor M2, resulting in that the voltage level at the pull-up node PU is pulled down from the third voltage level V1′ to a low level to reset the voltage level at the pull-up node PU;

(2) the reset signal input terminal RESET inputs a high level, and the fourth transistor M4 is turned on, so that the signal output terminal OUTPUT is coupled with the first signal input terminal VSS via the fourth transistor M4, resulting in that the voltage level at the signal output terminal OUTPUT is pulled down to a low level to reset the voltage level at the signal output terminal OUTPUT;

(3) the first clock signal input terminal CLKA inputs a low level, and the third transistor M3 is turned off due to the low level at the pull-up node PU, meanwhile the second clock signal input terminal CLKB inputs a high level, and the ninth transistor M9 is turned on; at this time, the second clock signal input terminal CLKB is coupled with the pull-down control node PD_CN, and the voltage level at the pull-down control node PD_CN is increased, resulting in that the fifth transistor M5 is turned on, the pull-down node PD is coupled with the second clock signal input terminal CLKB, and the voltage level at the pull-down node PD presents a high level;

(4) the voltage level at the pull-down node PD presents the high level, so that the eleventh transistor M11 is turned on; the second clock signal input terminal CLKB inputs a high level, so that the twelfth transistor M12 is turned on; at this time, the signal output terminal OUTPUT is coupled with the first signal input terminal VSS via the eleventh transistor M11 and the twelfth transistor M12, resulting in that the voltage level output from the signal output terminal OUTPUT is pulled down to a low level to reduce output noise at the signal output terminal OUTPUT.

(5) the voltage level at the pull-down node PD presents the high level, so that the tenth transistor M10 is turned on; and at this time, the pull-up node PU is coupled with the first signal input terminal VSS via the tenth transistor M10, resulting in that the voltage level at the pull-up node PU is pulled down to a low level to reduce output noise at the pull-up node PU.

It should be noted that the above (1) to (5) occur simultaneously in the reset and noise reduction stage rather than occurring sequentially.

The shift register in the present embodiment includes the input sub-circuit 1, the output sub-circuit 2 and the step-down sub-circuit 3. In the output stage, the step-down sub-circuit 3 is capable of pulling down the voltage level at the pull-up node PU from the second voltage level to the third voltage level after the voltage level at the pull-up node PU is pulled up to the second voltage level, such that the voltage at the pull-up node PU is instantly decreased, thereby avoiding occurrence of drift in the characteristic curve of the TFT device whose gate is coupled to the pull-up node PU, which in turn allows the TFT device to operate as normal, thereby avoiding display defects such as AD generated in the liquid crystal panel.

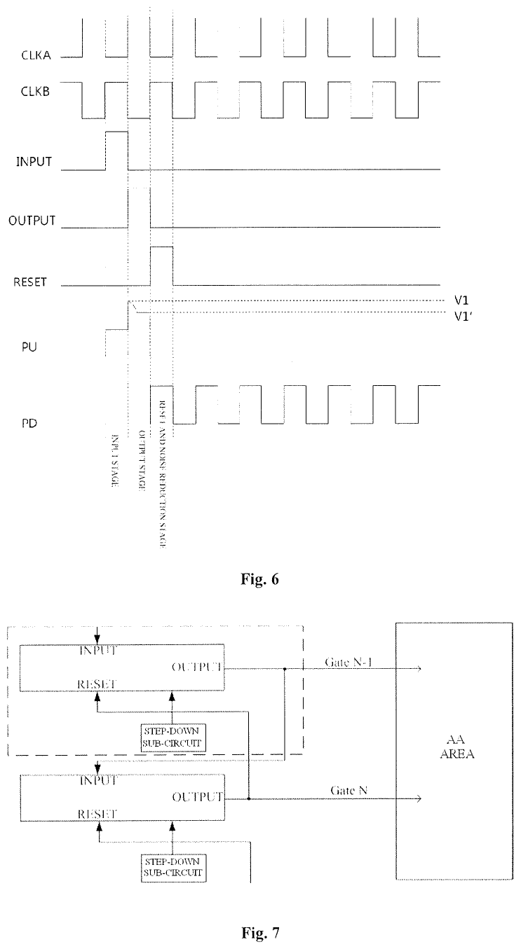

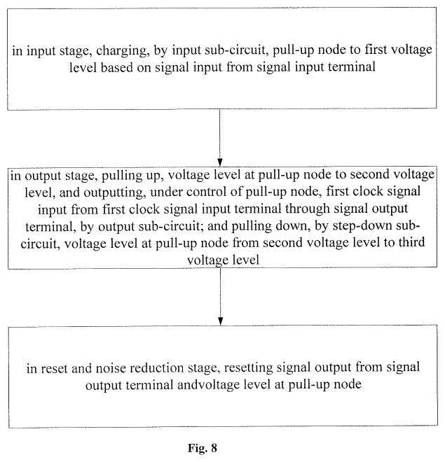

FIG. 7 is a schematic diagram illustrating a structure of a gate driver-on-array circuit according to an embodiment of the present disclosure. Referring to FIG. 7, the gate driver-on-array circuit includes a plurality of stages of the shift registers (as illustrated within the dashed box in FIG. 7) according to the embodiment as shown in FIG. 1.

A signal output from a gate driving signal generation unit of each stage of shift register serves as an input signal of an signal input terminal of a next stage of shift register; and a signal output from the signal output terminal of each stage of shift register is configured to drive a gate line and serves as a reset signal of a reset signal terminal of a previous stage of shift register.

It should be noted that, a signal output from the signal output terminal of each stage of shift register is configured to drive a gate line coupled with a display area (i.e., AA area) of a display panel.

The gate driver-on-array circuit of the present embodiment includes a plurality of stages of the shift registers according to the embodiment as shown in FIG. 1, the description of which may refer to that of the shift register of the embodiment as shown in FIG. 1, and will not be repeatedly described here.

The gate driver-on-array circuit includes a plurality of stages of the shift registers according to the embodiment as shown in FIG. 1. The shift register includes the input sub-circuit, the output sub-circuit and the step-down sub-circuit. In the output stage, the step-down sub-circuit is capable of pulling down the voltage level at the pull-up node from the second voltage level to the third voltage level after the voltage level at the pull-up node is pulled up to the second voltage level, such that the voltage at the pull-up node is instantly decreased, thereby avoiding occurrence of drift in the characteristic curve of the TFT device whose gate is coupled to the pull-up node, which in turn allows the TFT device to operate as normal, thereby avoiding display defects such as AD generated in the liquid crystal panel.

An embodiment of the present disclosure further provides a display device including the gate driver-on-array circuit according to the embodiment as shown in FIG. 7. The display device may be any product or part with display function, such as a liquid crystal display panel, an electronic paper, a mobile phone, a tablet computer, a television, a display, a laptop computer, a digital frame, a navigator or the like.

The display device in the present embodiment includes the gate driver-on-array circuit according to the embodiment as shown in FIG. 7, in which the shift register includes the input sub-circuit, the output sub-circuit and the step-down sub-circuit. In the output stage, the step-down sub-circuit is capable of pulling down the voltage level at the pull-up node from the second voltage level to the third voltage level after the voltage level at the pull-up node is pulled up to the second voltage level, such that the voltage at the pull-up node is instantly decreased, thereby avoiding occurrence of drift in the characteristic curve of the TFT device whose gate is coupled to the pull-up node, which in turn allows the TFT device to operate as normal, thereby avoiding display defects such as AD generated in the liquid crystal panel.

An embodiment of the present disclosure further provides a method for driving a gate driver-on-array circuit. FIG. 8 is a flow chart illustrating a method for driving a gate driver-on-array circuit according to an embodiment of the present disclosure. The gate driver-on-array circuit includes a plurality of stages of the shift registers according to the embodiment shown in FIG. 1 or FIG. 4. As shown in FIG. 8, the driving method includes:

in an input stage, charging, by the input sub-circuit, the pull-up node to the first voltage level based on the signal input from the signal input terminal;

in an output stage, pulling up, the voltage level at the pull-up node to the second voltage level, and outputting, under control of the pull-up node, the first clock signal input from the first clock signal input terminal through the signal output terminal, by the output sub-circuit; and pulling down, by the step-down sub-circuit, the voltage level at the pull-up node from the second voltage level to the third voltage level, the third voltage level being greater than the first voltage level.

In a case where the gate driver-on-array circuit includes a plurality of stages of the shift registers according to the embodiment shown in FIG. 4, the driving method further includes: in a reset and noise reduction stage, resetting the signal output from the signal output terminal and the voltage level at the pull-up node.

When the method for driving the gate driver-on-array circuit of the present embodiment is adopted for driving the gate driver-on-array circuit of the embodiment shown in FIG. 7, in which the shift register includes the input sub-circuit, the output sub-circuit and the step-down sub-circuit, in the output stage, the step-down sub-circuit is capable of pulling down the voltage level at the pull-up node from the second voltage level to the third voltage level after the voltage level at the pull-up node is pulled up to the second voltage level, such that the voltage at the pull-up node is instantly decreased, thereby avoiding occurrence of drift in the characteristic curve of the TFT device whose gate is coupled to the pull-up node, which in turn allows the TFT device to operate as normal, thereby avoiding display defects such as AD generated in the liquid crystal panel.

It can be understood that the foregoing implementations are merely exemplary implementations used for describing the principle of the present disclosure, but the present disclosure is not limited thereto. Those of ordinary skilled in the art may make various variations and improvements without departing from the spirit and essence of the present disclosure, and these variations and improvements shall fall into the protection scope of the present disclosure.

1-15. (canceled)

16. A shift register, comprising an input sub-circuit, an output sub-circuit and a step-down sub-circuit, wherein
the input sub-circuit is coupled to a signal input terminal and a pull-up node, and is configured to, in an input stage, charge the pull-up node to a first voltage level based on a signal input from the signal input terminal, the pull-up node being a node connected in between the input sub-circuit, the output sub-circuit and the step-down sub-circuit;
the output sub-circuit is coupled to a first clock signal input terminal, a signal output terminal, the step-down sub-circuit and the pull-up node, and is configured to, in an output stage, pull up a voltage level at the pull-up node to a second voltage level;
the step-down sub-circuit is further coupled to the pull-up node and the signal output terminal, and is configured to, in the output stage, pull down the voltage level at the pull-up node from the second voltage level to a third voltage level after the voltage level at the pull-up node is pulled up to the second voltage level; and
the output sub-circuit is further configured to, in the output stage, output a first clock signal input from the first clock signal input terminal through the signal output terminal under control of the pull-up node.

17. The shift register of claim 16, wherein the step-down sub-circuit comprises a switching transistor having a first electrode coupled to the output sub-circuit and the pull-up node, a second electrode coupled to a control electrode of the switching transistor, the output sub-circuit and the signal output terminal, and the control electrode coupled to the output sub-circuit and the signal output terminal.

18. The shift register of claim 16, wherein the input sub-circuit comprises a first transistor having a first electrode coupled to the signal input terminal and a second electrode coupled to the pull-up node.

19. The shift register of claim 16, wherein the output sub-circuit comprises a third transistor and a storage capacitor;
a first electrode of the third transistor is coupled to the first clock signal input terminal, a second electrode of the third transistor is coupled to a second terminal of the storage capacitor and the step-down sub-circuit, and a control electrode of the third transistor is coupled to the pull-up node and a first terminal of the storage capacitor.

20. The shift register of claim 16, further comprising an output reset sub-circuit, a pull-up node reset sub-circuit, a pull-down sub-circuit, a pull-down control sub-circuit, a noise reduction sub-circuit and a step-up sub-circuit, wherein
the output reset sub-circuit is coupled to a reset signal input terminal, a first signal input terminal and the signal output terminal, and is configured to reset the signal output from the signal output terminal;
the pull-up node reset sub-circuit is coupled to the reset signal input terminal, the first signal input terminal and the pull-up node, and is configured to reset the voltage level at the pull-up node;
the pull-down control sub-circuit is coupled to a pull-down node and a second clock signal input terminal, and is configured to control a voltage level at the pull-down node based on a second clock signal input from the second clock signal input terminal, the pull-down node being a node connected in between the pull-down control sub-circuit and the pull-down sub-circuit;
the pull-down sub-circuit is coupled to the pull-down node, the pull-up node, the pull-down control sub-circuit and the first signal input terminal, and is configured to pull down, under control of the voltage level at the pull-up node, the voltage level at the pull-down node through a first signal input from the first signal input terminal;
the noise reduction sub-circuit is coupled to the input sub-circuit, the first signal input terminal, the pull-down node, the pull-up node, the output sub-circuit, the signal output terminal and the second clock signal input terminal, and is configured to reduce output noise at the pull-up node and output noise at the signal output terminal through the first signal input from the first signal input terminal; and
the step-up sub-circuit is coupled to the signal input terminal, the input sub-circuit, the second clock signal input terminal and the pull-up node, and is configured to step up the signal input from the signal input terminal based on the second clock signal input from the second clock signal input terminal.

21. The shift register of claim 20, wherein the output reset sub-circuit comprises a fourth transistor having a first electrode coupled to the step-down sub-circuit, the output sub-circuit and the signal output terminal, a second electrode coupled to the first signal input terminal, and a control electrode coupled to the reset signal input terminal.

22. The shift register of claim 20, wherein the pull-up node reset sub-circuit comprises a second transistor having a first electrode coupled to the pull-up node, a second electrode coupled to the first signal input terminal, and a control electrode coupled to the reset signal input terminal.

23. The shift register of claim 20, wherein the pull-down sub-circuit includes a sixth transistor and an eighth transistor;
a first electrode of the sixth transistor is coupled to the pull-down node, a second electrode of the sixth transistor is coupled to the first signal input terminal, and a control electrode of the sixth transistor is coupled to the pull-up node; and
a first electrode of the eighth transistor is coupled to the pull-down control sub-circuit, a second electrode of the eighth transistor is coupled to the first signal input terminal, and a control electrode of the eighth transistor is coupled to the pull-up node.

24. The shift register of claim 20, wherein the pull-down control sub-circuit includes a fifth transistor, a ninth transistor and a pull-down control node;
a first electrode of the fifth transistor is coupled to a first electrode of the ninth transistor and the second clock signal input terminal, a second electrode of the fifth transistor is coupled to the pull-down node, and a control electrode of the fifth transistor is coupled to the pull-down control node; and
a second electrode of the ninth transistor is coupled to the pull-down control node, and a control electrode of the ninth transistor is coupled to the second clock signal input terminal.

25. The shift register of claim 20, wherein the noise reduction sub-circuit comprises a tenth transistor, an eleventh transistor and a twelfth transistor;
a first electrode of the tenth transistor is coupled to the input sub-circuit and the pull-up node, a second electrode of the tenth transistor is coupled to the first signal input terminal, and a control electrode of the tenth transistor is coupled to the pull-down node;
a first electrode of the eleventh transistor is coupled to the output sub-circuit and the signal output terminal, a second electrode of the eleventh transistor is coupled to the first signal input terminal, and a control electrode of the eleventh transistor is coupled to the pull-down node; and
a first electrode of the twelfth transistor is coupled to the signal output terminal, a second electrode of the twelfth transistor is coupled to the first signal input terminal, and a control electrode of the twelfth transistor is coupled to the second clock signal input terminal.

26. The shift register of claim 20, wherein the step-up sub-circuit comprises a thirteenth transistor having a first electrode coupled to the signal input terminal, a second electrode coupled to the pull-up node, and a control electrode coupled to the second clock signal input terminal.

27. A gate driver-on-array circuit, comprising a plurality of stages of shift registers each being the shift register according to claim 16, wherein
a signal output from a gate driving signal generation unit of each stage of shift register serves as an input signal of the signal input terminal of a next stage of shift register; and
a signal output from the signal output terminal of each stage of shift register is configured to drive a gate line and serves as a reset signal of a reset signal terminal of a previous stage of shift register.

28. A display device, comprising the gate driver-on-array circuit according to claim 27.

29. A method for driving a gate driver-on-array circuit, the gate driver-on-array circuit comprising a plurality of stages of shift registers, each of which comprises an input sub-circuit, an output sub-circuit and a step-down sub-circuit, wherein
the input sub-circuit is coupled to a signal input terminal and a pull-up node, and is configured to, in an input stage, charge the pull-up node to a first voltage level based on a signal input from the signal input terminal, the pull-up node being a node connected in between the input sub-circuit, the output sub-circuit and the step-down sub-circuit;
the output sub-circuit is coupled to a first clock signal input terminal, a signal output terminal, the step-down sub-circuit and the pull-up node, and is configured to, in an output stage, pull up a voltage level at the pull-up node to a second voltage level;
the step-down sub-circuit is further coupled to the pull-up node and the signal output terminal, and is configured to, in the output stage, pull down the voltage level at the pull-up node from the second voltage level to a third voltage level after the voltage level at the pull-up node is pulled up to the second voltage level; and
sub-circuit is further configured to, in the output stage, output a first clock signal input from the first clock signal input terminal through the signal output terminal under control of the pull-up node,
wherein the method comprises:
in an input stage, charging, by the input sub-circuit, the pull-up node to the first voltage level based on the signal input from the signal input terminal; and
in an output stage, pulling up the voltage level at the pull-up node to the second voltage level, and outputting, under control of the pull-up node, the first clock signal input from the first clock signal input terminal through the signal output terminal, by the output sub-circuit; and pulling down, by the step-down sub-circuit, the voltage level at the pull-up node from the second voltage level to the third voltage level.

30. The method of claim 29, wherein each of the plurality of stages of shift registers further comprises an output reset sub-circuit, a pull-up node reset sub-circuit, a pull-down sub-circuit, a pull-down control sub-circuit, a noise reduction sub-circuit and a step-up sub-circuit,
the output reset sub-circuit is coupled to a reset signal input terminal, a first signal input terminal and the signal output terminal, and is configured to reset the signal output from the signal output terminal;
the pull-up node reset sub-circuit is coupled to the reset signal input terminal, the first signal input terminal and the pull-up node, and is configured to reset the voltage level at the pull-up node;
the pull-down control sub-circuit is coupled to a pull-down node and a second clock signal input terminal, and is configured to control a voltage level at the pull-down node based on a second clock signal input from the second clock signal input terminal, the pull-down node being a node connected in between the pull-down control sub-circuit and the pull-down sub-circuit;
the pull-down sub-circuit is coupled to the pull-down node, the pull-up node, the pull-down control sub-circuit and the first signal input terminal, and is configured to pull down, under control of the voltage level at the pull-up node, the voltage level at the pull-down node through a first signal input from the first signal input terminal;
the noise reduction sub-circuit is coupled to the input sub-circuit, the first signal input terminal, the pull-down node, the pull-up node, the output sub-circuit, the signal output terminal and the second clock signal input terminal, and is configured to reduce output noise at the pull-up node and output noise at the signal output terminal through the first signal input from the first signal input terminal; and
the step-up sub-circuit is coupled to the signal input terminal, the input sub-circuit, the second clock signal input terminal and the pull-up node, and is configured to step up the signal input from the signal input terminal based on the second clock signal input from the second clock signal input terminal,
wherein the method further comprises:
in a reset and noise reduction stage, resetting the signal output from the signal output terminal and the voltage level at the pull-up node.

31. The shift register of claim 17, further comprising an output reset sub-circuit, a pull-up node reset sub-circuit, a pull-down sub-circuit, a pull-down control sub-circuit, a noise reduction sub-circuit and a step-up sub-circuit, wherein
the output reset sub-circuit is coupled to a reset signal input terminal, a first signal input terminal and the signal output terminal, and is configured to reset the signal output from the signal output terminal;
the pull-up node reset sub-circuit is coupled to the reset signal input terminal, the first signal input terminal and the pull-up node, and is configured to reset the voltage level at the pull-up node;
the pull-down control sub-circuit is coupled to a pull-down node and a second clock signal input terminal, and is configured to control a voltage level at the pull-down node based on a second clock signal input from the second clock signal input terminal, the pull-down node being a node connected in between the pull-down control sub-circuit and the pull-down sub-circuit;
the pull-down sub-circuit is coupled to the pull-down node, the pull-up node, the pull-down control sub-circuit and the first signal input terminal, and is configured to pull down, under control of the voltage level at the pull-up node, the voltage level at the pull-down node through a first signal input from the first signal input terminal;
the noise reduction sub-circuit is coupled to the input sub-circuit, the first signal input terminal, the pull-down node, the pull-up node, the output sub-circuit, the signal output terminal and the second clock signal input terminal, and is configured to reduce output noise at the pull-up node and output noise at the signal output terminal through the first signal input from the first signal input terminal; and
the step-up sub-circuit is coupled to the signal input terminal, the input sub-circuit, the second clock signal input terminal and the pull-up node, and is configured to step up the signal input from the signal input terminal based on the second clock signal input from the second clock signal input terminal.

32. The shift register of claim 18, further comprising an output reset sub-circuit, a pull-up node reset sub-circuit, a pull-down sub-circuit, a pull-down control sub-circuit, a noise reduction sub-circuit and a step-up sub-circuit, wherein
the output reset sub-circuit is coupled to a reset signal input terminal, a first signal input terminal and the signal output terminal, and is configured to reset the signal output from the signal output terminal;
the pull-up node reset sub-circuit is coupled to the reset signal input terminal, the first signal input terminal and the pull-up node, and is configured to reset the voltage level at the pull-up node;
the pull-down control sub-circuit is coupled to a pull-down node and a second clock signal input terminal, and is configured to control a voltage level at the pull-down node based on a second clock signal input from the second clock signal input terminal, the pull-down node being a node connected in between the pull-down control sub-circuit and the pull-down sub-circuit;
the pull-down sub-circuit is coupled to the pull-down node, the pull-up node, the pull-down control sub-circuit and the first signal input terminal, and is configured to pull down, under control of the voltage level at the pull-up node, the voltage level at the pull-down node through a first signal input from the first signal input terminal;
the noise reduction sub-circuit is coupled to the input sub-circuit, the first signal input terminal, the pull-down node, the pull-up node, the output sub-circuit, the signal output terminal and the second clock signal input terminal, and is configured to reduce output noise at the pull-up node and output noise at the signal output terminal through the first signal input from the first signal input terminal; and
the step-up sub-circuit is coupled to the signal input terminal, the input sub-circuit, the second clock signal input terminal and the pull-up node, and is configured to step up the signal input from the signal input terminal based on the second clock signal input from the second clock signal input terminal.

33. The shift register of claim 19, further comprising an output reset sub-circuit, a pull-up node reset sub-circuit, a pull-down sub-circuit, a pull-down control sub-circuit, a noise reduction sub-circuit and a step-up sub-circuit, wherein
the output reset sub-circuit is coupled to a reset signal input terminal, a first signal input terminal and the signal output terminal, and is configured to reset the signal output from the signal output terminal;
the pull-up node reset sub-circuit is coupled to the reset signal input terminal, the first signal input terminal and the pull-up node, and is configured to reset the voltage level at the pull-up node;
the pull-down control sub-circuit is coupled to a pull-down node and a second clock signal input terminal, and is configured to control a voltage level at the pull-down node based on a second clock signal input from the second clock signal input terminal, the pull-down node being a node connected in between the pull-down control sub-circuit and the pull-down sub-circuit;
the pull-down sub-circuit is coupled to the pull-down node, the pull-up node, the pull-down control sub-circuit and the first signal input terminal, and is configured to pull down, under control of the voltage level at the pull-up node, the voltage level at the pull-down node through a first signal input from the first signal input terminal;
the noise reduction sub-circuit is coupled to the input sub-circuit, the first signal input terminal, the pull-down node, the pull-up node, the output sub-circuit, the signal output terminal and the second clock signal input terminal, and is configured to reduce output noise at the pull-up node and output noise at the signal output terminal through the first signal input from the first signal input terminal; and
the step-up sub-circuit is coupled to the signal input terminal, the input sub-circuit, the second clock signal input terminal and the pull-up node, and is configured to step up the signal input from the signal input terminal based on the second clock signal input from the second clock signal input terminal.

34. The shift register of claim 16, wherein the third voltage level is greater than the first voltage level.

35. A gate driver-on-array circuit, comprising a plurality of stages of shift registers each being the shift register according to claim 20, wherein
a signal output from a gate driving signal generation unit of each stage of shift register serves as an input signal of the signal input terminal of a next stage of shift register; and
a signal output from the signal output terminal of each stage of shift register is configured to drive a gate line and serves as a reset signal of a reset signal terminal of a previous stage of shift register.
